(19) United States
(12) Patent Application Publication
(10) Pub. No.: US 2006/0098500 A1
(43) Pub. Date: May 11, 2006

(54) Truly random number generating circuit and method thereof

(76) Inventors: Hongyi Chen, Beijing (CN); Zhun Huang, Beijing (CN); Guoqiang Bai, Beijing (CN)

Correspondence Address: J C PATENTS, INC., 4 VENTURE, SUITE 250, IRVINE, CA, 92618, US

(21) Appl. No.: 10/985,158

(22) Filed: Nov. 9, 2004

(51) Int. Cl. G11C 5/14

(52) U.S. Cl. 365/189.09

(57) ABSTRACT

A chaotic circuit for truly random number generation is provided. The chaotic dynamical system used in the circuit is implemented based on the charge redistribution of capacitors. The random number generator circuit is a switched network including four capacitors and eight switches that are controlled by two-phase non-overlapping clock signals. The two clocks turn on switches alternatively. The circuit further includes inverter chain and amplifier. When a first clock signal turns on, four capacitors are charged by the inverter chain and the amplifier that connected as a unity gain buffer. When a second clock signal turns on, the charges are redistributed. The voltage of output terminal of the amplifier is function of its previous status, and thus a random bit stream is generated at an output terminal of the inverter chain. A smaller core area and lower power consumption is provided since circuit is simpler and no resistor is required.

### BACKGROUND OF THE INVENTION

1. Field of Invention

The present invention relates to a chaotic circuit suitable for truly random number generation, and more particularly to a truly random number generating circuit based on charge redistribution of capacitors.

2. Description of the Related Art

Random numbers are widely used in simulation, testing and communications, especially in information security. Some applications, such as cryptography, require secure random numbers, which is neither predicted in spite of any knowledge of preceding numbers in the sequence, nor are deduced when succeeding numbers are known.

In general, there are two basic types of generators: pseudo-random number generators (PRNGs) and random number generators (RNGs), which are also called truly random number generators (TRNGs) to be distinguished from PRNGs.

PRNGs are deterministic algorithms capable of generating sequences that appear random-like from many aspects and pass nearly all statistical tests. Many applications prefer PRNGs because they can be implemented with fast and simple software routine. However, they are periodic and deterministic at the same time, and predictable when having sufficient computer power. That is, security to PRNGs completely depends on complexity of algorithms. Nowadays, PRNGs are inappropriate when ultimate security is required.

In contrast with PRNGs, the randomness of TRNGs comes from intrinsically random physical process, such as thermal noise and radioactive decay. TRNGs convert the randomness of a physical process into a sequence of discrete random variables, most usually binary ones, and derive the desired distribution from them.

The core of a TRNG is an unpredictable and unmeasurable random physical process. But in circuit, it is difficult to find such a random and feasible physical process, which is a must when designing a TRNG circuit. Several phenomena are known to be available for circuit, such as thermal noise of a resistor that is most often used. Because precise amplifiers are needed to measure thermal noise, it is not easy to reduce chip size and power consumption.

In recent years, rapid progress has been made in nonlinear science, and it is found that implementation of chaotic behavior is also suitable for circuit especially for VLSI. Chaotic systems are thus desired to be used as sources of physical randomness based on an on-chip design complying with small core size and low power consumption.

### SUMMARY OF THE INVENTION

A random number generating circuit for VLSI purpose is provided in this present invention. The random number generating circuit mainly includes four capacitors and eight switches that are controlled by two-phase non-overlapping clock signals, the first clock signal and the second clock signal. The random number generating circuit further includes an operational amplifier coupling to the aforementioned capacitors/switches network, and a chain of two inverters coupled to the operational amplifier and the capacitors/switches network. The two clock signals turn on the switches alternatively. When the first clock signal turns on, the four capacitors are charged by the inverter chain that performs piecewise function, and the operational amplifier that connected as a unity gain buffer. When the second clock signal turns on, some switches are connected and thus charges are redistributed. Voltage at the output terminal of the operational amplifier is then a function of its previous value in time domain.

According to the law of conservation of charges, when the circuit eventually reaches equilibrium after the second clock signal turns on, the voltage at the output terminal of the operational amplifier is:

$${V}_{7} ( n + 1 ) = \{ \begin{matrix}{bV}_{7} ( n ) - {aV}_{OL} , {V}_{7} ( n ) < {V}_{t} \\ {bV}_{7} ( n ) - {aV}_{OH} , {V}_{7} ( n ) > {V}_{t}\end{matrix} \\ a = \frac{{C}_{1} {C}_{2} {C}_{3}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}} \\ b = \frac{2 {C}_{1} {C}_{2} {C}_{3} + {C}_{1} {C}_{2} {C}_{4} + {C}_{1} {C}_{3} {C}_{4} + {C}_{2} {C}_{3} {C}_{4}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}}$$

where (n+1) referring to current status, n referring to previous status, where n being a positive integer.

That is, voltage at the output terminal of the operational amplifier is an iterated piecewise linear map when the first clock signal and the second clock signal switches alternatively. Therefore a discrete dynamical system is generated by the continuous cycles of such an iterated map.

To make the circuit chaotic, the parameters are chosen to satisfy 1<b<2, bVₜ−aV_{OH}<Vₜ<bVₜ−aV_{OL}. The binary sequence outputted at the output terminal of the operational amplifier is random. To achieve higher entropy rate, value of b close to 2 is preferred. Parameter a and b are determined by ratios of the four capacitors, but the absolute values are not insignificant. Smaller capacitors obtain faster speed, smaller area, less power consumption, and meanwhile larger parameter errors caused by mismatch and parasitical effect.

The random number generating circuit in this present invention is fabricated in a 0.8 μm CMOS technology. A core size of the random number generating circuit based on the feature size is less than 60×70 μm². And a simulation by HSpice of the random number generating circuit shows the current of power dissipation is less than 200 μA at a power supply voltage of 5V and at a clock frequency of 1 MHz.

Therefore, a chaotic circuit suitable for VLSI is provided in this present invention, which is better at area and power consumption than prior technologies. Uncertainty demanded by cryptography is provided according to the random number generating circuit in the present invention. It can be used as a source of randomness of truly random number generator with an appropriate algorithm that could derive uniform distributed sequence from bit stream at the inverter chain output.

### BRIEF DESCRIPTION OF THE DRAWINGS

FIG. 1 is a schematic circuit diagram illustrating a truly random number generating circuit according to one embodiment of the present invention.

### DESCRIPTION OF THE EMBODIMENTS

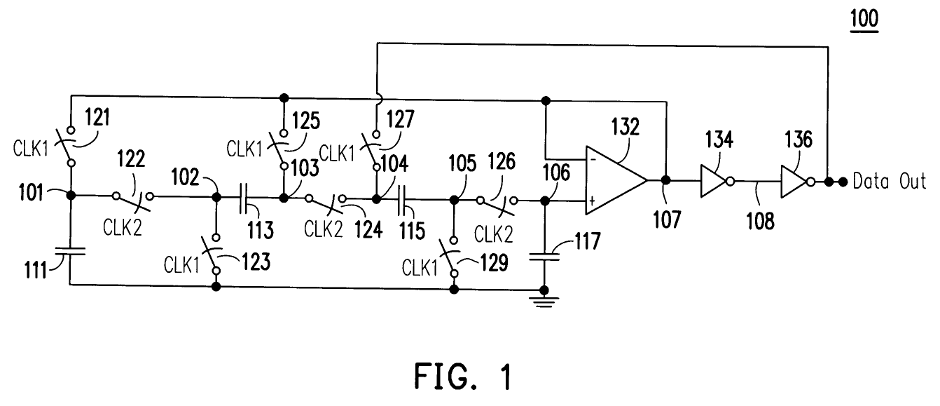

Referring to FIG. 1, it illustrates a schematic circuit diagram of a truly random number generating circuit according to one embodiment of the present invention. The random number generating circuit mainly includes four capacitors 111, 113, 115, and 117, and eight switches 121, 122, 123, 124, 125, 126, 127, 129. The random number generating circuit further includes an operational amplifier 132 coupling to the main portion of the circuit and performing unity gain, and two inverters 134 and 136 connected in series and are coupled to the operational amplifier. Two clock signals CLK1 and CLK2 are provided to control the switches, where the two clock signals are non-overlapping in phase and turn on switches alternatively.

A detail network description of the random number generating circuit is introduced hereinafter. The capacitor 111 is coupled to a ground and a node 101. The capacitor 113 is coupled to a node 102 and a node 103. The third capacitor 115 is coupled to a node 104 and a node 105. And the fourth capacitor 117 is coupled to a node 106 and the ground. The switch 121 is coupled to the node 101 and a node 107 and controlled by the clock signal CLK1. The switch 122 is coupled to the node 101 and 102 and controlled by the clock signal CLK2. The switch 123 is coupled to the node 102 and the ground and controlled by the clock signal CLK1. The switch 124 is coupled to the node 103 and the node 104 and controlled by the clock signal CLK2. The switch 125 is coupled to the node 103 and the node 107 and controlled by the clock signal CLK1. The switch 126 is coupled to the node 105 and the node 106 and controlled by the clock signal CLK2. The switch 127 is coupled to the node 104 and the output terminal of the second inverter 136, which is also the data output terminal of the random number generating circuit, and controlled by the clock signal CLK1. The switch 129 is coupled tot he node 105 and the ground and controlled by clock CLK1.

Moreover, the operational amplifier 132 has a negative input terminal coupling to the node 107, a positive input terminal coupling to the node 106, and an output terminal coupling to the node 107. The first inverter has an input terminal coupling to the node 107, and an output terminal coupling to a node 108. The second inverter has an input terminal coupling to the node 108, and an output terminal being the data output of the random circuit generating circuit in this present invention.

The two clock signals CLK1 and CLK2 are two phase non-overlapping clock signals, which turn on switches alternatively. When CLK1 turns on, four capacitors are charged by the inverter chain 134 and 135 that so that a piecewise function of voltage is provided, and the operational amplifier 132 performs as a unity gain buffer. When CLK2 turns on, switches 122, 124, and 126 are connected and thus charges are redistributed. Voltage at node 107 is a function of its previous value thereby.

According to the law of conservation of charge, when the random number generating circuit reaches equilibrium after CLK2 turns on, the voltage at node 107 is:

$${V}_{107} ( n + 1 ) = \{ \begin{matrix}{bV}_{107} ( n ) - {aV}_{OL} , {V}_{107} ( n ) < {V}_{t} \\ {bV}_{107} ( n ) - {aV}_{OH} , {V}_{107} ( n ) > {V}_{t}\end{matrix} \\ a = \frac{{C}_{1} {C}_{2} {C}_{3}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}} \\ b = \frac{2 {C}_{1} {C}_{2} {C}_{3} + {C}_{1} {C}_{2} {C}_{4} + {C}_{1} {C}_{3} {C}_{4} + {C}_{2} {C}_{3} {C}_{4}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}}$$

for 1<b<2, bVₜ−aV_{OH}<Vₜ<bVₜ−aV_{OL}, where (n+1) referring to current status, n referring to a previous status, where n being a positive integer.

Notice that although the operational amplifier has a gain of unity, the accuracy requirement of the random generating circuit of this present invention is low, i.e., the gain of the operational amplifier is not necessary to be unity. Any number being about unity is within the scope of the present invention.

Also notice that the approach to implement a piecewise linear map chaotic behavior is based on charge redistribution of capacitors. A much less area and power consumption is thus obtained, for circuit is simplified as opposed to circuits that include resistors and other devices in prior technologies. Since the parameters of the circuit in this present invention mainly depend on the ratio of capacitance, fabrication of the circuit is thus easier to be controlled in VLSI technology.

It is to also to be noted that more number of capacitors can apply to the random number generating circuit in this present invention for a more complicated map. Any block implementing an iterated map other than piecewise linear map is also within the scope of the present invention; therefore the inverter chain can be replaced.

Although the invention has been described with reference to a particular embodiment thereof, it will be apparent to those skilled in the art that modifications to the described embodiment may be made without departing from the spirit of the invention. Accordingly, the scope of the invention will be defined by the attached claims and not by the above detailed description.

What is claimed is:

1. A random number generating circuit, controlled by a first clock signal and a second clock signal, comprising:
a charge storing/redistributing means;
a unity gain means coupling to the charging/charge-redistributing means; and
a iterated map generating means coupling to the unity gain means and feeding back to the charge storing/redistributing means,
wherein the first clock signal and the second clock signal switch alternatively, when the first clock signal turns on, the charge storing/redistributing means are charged with a plurality of charges, and when the second clock signal turns on, the charges are redistributed.

2. The random number generating circuit as recited in claim 1, wherein the first clock signal and the second clock signal have non-overlapping phases.

3. The random number generating circuit as recited in claim 1, wherein the charge storing/redistributing means comprises:
a plurality of capacitors; and
a plurality of switches.

4. The random number generating circuit as recited in claim 1, wherein the charge storing/redistributing means comprises:
a first charge storing device, coupling to a first node and a ground;
a second charge storing device, coupling to a second node and a third node;
a third charge storing device, coupling to a fourth node and a fifth node;
a fourth charge storing device coupling to a sixth node and the ground;
a first switching device, coupling to the first node and a seventh node, controlled by the first clock signal;
a second switching device, coupling to the first node and the second node, controlled by the second clock signal;
a third switching device, coupling to the second node and the ground, controlled by the first clock signal;
a fourth switching device, coupling to the third node and the fourth node, controlled by the second clock signal;
a fifth switching device, coupling to the third node and the seventh node, controlled by the first clock signal;
a sixth switching device, coupling to the fifth node and the sixth node, controlled by the second clock signal;
a seventh switching device, coupling to the fourth node and an data output, controlled by the first clock signal; and
an eighth switching device, coupling to the fifth node and the ground, controlled by the first clock signal.

5. The random number generating circuit as recited in claim 4, wherein the unity gain means is an operational amplifier having a negative input terminal coupling to the seventh node, a positive input terminal coupling to the sixth node, and the data output terminal coupling to the seventh node.

6. The random number generating circuit as recited in claim 4, wherein the iterated map generating means comprises two inverting means coupled in series generating a piecewise linear map, coupling to the seventh node and the data output node.

7. The random number generating circuit as recited in claim 4, wherein the first charge storing device, the second charge storing device, the third charge storing device, and the charge fourth storing device are capacitors.

8. The random number generating circuit as recited in claim 7, wherein the first charge storing device has a first capacitance C₁, the second charge storing device has a second capacitance C₂, the third charge storing device has a third capacitance C₃, the fourth charge storing device has a fourth capacitance C₄, a voltage of the seventh node is V₇ and is a function of its previous value, a low level output voltage of the inverting means is V_{OL}, a high level voltage of the inverting means is V_{OH}, an intermediate voltage level of the inverting means is Vₜ, the voltage
$${V}_{7} ( n + 1 ) = \{ \begin{matrix}{bV}_{7} ( n ) - {aV}_{OL} , {V}_{7} ( n ) < {V}_{t} \\ {bV}_{7} ( n ) - {aV}_{OH} , {V}_{7} ( n ) > {V}_{t}\end{matrix} \\ a = \frac{{C}_{1} {C}_{2} {C}_{3}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}} \\ b = \frac{2 {C}_{1} {C}_{2} {C}_{3} + {C}_{1} {C}_{2} {C}_{4} + {C}_{1} {C}_{3} {C}_{4} + {C}_{2} {C}_{3} {C}_{4}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}}$$
for 1<b<2, bV₇(n)−aV_{OH}<V₇(n)<bV₇(n)−aV_{OL}, where (n+1) referring to current status, n referring to previous status, where n being a positive integer.

9. The random number generating circuit as recited in claim 1, wherein the random number generating circuit is fabricated on an integrated chip.

10. The random number generating circuit as recited in claim 1, wherein the random number generating circuit is fabricated in a 0.8 μm CMOS technology, a core size of the random number generating circuit is less than 60×70 μm², and a simulation by HSpice of the random number generating circuit shows the current of power dissipation is less than 200 μA at a power supply voltage of 5V and at a clock frequency of 1 MHz.

11. A random number generating circuit, comprising:
a first charge storing device, coupling to a first node and a ground;
a second charge storing device, coupling to a second node and a third node;
a third charge storing device, coupling to a fourth node and a fifth node;
a fourth charge storing device coupling to a sixth node and the ground;
a first switching device, coupling to the first node and a seventh node, controlled by the first clock signal;
a second switching device, coupling to the first node and the second node, controlled by the second clock signal;
a third switching device, coupling to the second node and the ground, controlled by the first clock signal;
a fourth switching device, coupling to the third node and the fourth node, controlled by the second clock signal;
a fifth switching device, coupling to the third node and the seventh node, controlled by the first clock signal;
a sixth switching device, coupling to the fifth node and the sixth node, controlled by the second clock signal;
a seventh switching device, coupling to the fourth node and an data output, controlled by the first clock signal;
an eighth switching device, coupling to the fifth node and the ground, controlled by the first clock signal;
an operational amplifier, having a negative input terminal coupling to the seventh node, a positive input terminal coupling to the sixth node, and an output terminal coupling to the seventh node;
a first inverter, having an input terminal coupling to the seventh node, and an output terminal coupling to an eighth node; and
a second inverter, having an input terminal coupling to the eighth node, and an output terminal coupling to the data output.

12. The random number generating circuit as recited in claim 11, wherein the first charge storing device has a first capacitance C₁, the second charge storing device has a second capacitance C₂, the third charge storing device has a third capacitance C₃, the fourth charge storing device has a fourth capacitance C₄, a voltage of the seventh node is V₇ and is a function of its previous value, a low level output voltage of the inverting means is V_{OL}, a high level voltage of the inverting means is V_{OH}, an intermediate voltage level of the inverting means is Vₜ, the voltage
$${V}_{7} ( n + 1 ) = \{ \begin{matrix}{bV}_{7} ( n ) - {aV}_{OL} , {V}_{7} ( n ) < {V}_{t} \\ {bV}_{7} ( n ) - {aV}_{OH} , {V}_{7} ( n ) > {V}_{t}\end{matrix} \\ a = \frac{{C}_{1} {C}_{2} {C}_{3}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}} \\ b = \frac{2 {C}_{1} {C}_{2} {C}_{3} + {C}_{1} {C}_{2} {C}_{4} + {C}_{1} {C}_{3} {C}_{4} + {C}_{2} {C}_{3} {C}_{4}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}}$$
for 1<b<2, bV₇(n)−aV_{OH}<V₇(n)<bV₇(n)−aV_{OL}, where (n+1) referring to current status, n referring to previous status, where n being a positive integer.

13. A random number generating method, comprising:
providing a first reference number V_{OL}, a second reference number V_{OH}, and a third reference number Vₜ;
providing a first constant C₁, a second constant C₂, a third constant C₃, and a fourth constant C₄;
defining a first parameter a and a second parameter b, where
$$a = \frac{{C}_{1} {C}_{2} {C}_{3}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}}$$
$$b = \frac{2 {C}_{1} {C}_{2} {C}_{3} + {C}_{1} {C}_{2} {C}_{4} + {C}_{1} {C}_{3} {C}_{4} + {C}_{2} {C}_{3} {C}_{4}}{{C}_{1} {C}_{2} {C}_{3} + {C}_{1} {C}_{2} {C}_{4} + {C}_{1} {C}_{3} {C}_{4} + {C}_{2} {C}_{3} {C}_{4}} ;$$
$$and$$
generating a time dependent random number V₇ according to the following function:
$${V}_{7} ( n + 1 ) = \{ \begin{matrix}{bV}_{7} ( n ) - {aV}_{OL} , {V}_{7} ( n ) < {V}_{t} \\ {bV}_{7} ( n ) - {aV}_{OH} , {V}_{7} ( n ) > {V}_{t}\end{matrix}$$
for 1<b<2, bVₜ−aV_{OH}<Vₜ<bVₜ−aV_{OL}, where (n+1) referring to current status, n referring to previous status, n being a positive integer.
